(19) United States
(12) Patent Application Publication
(10) Pub. No.: US 2024/0202403 A1
(43) Pub. Date: Jun. 20, 2024

(54) APPARATUSES, METHODS, AND COMPUTER PROGRAM PRODUCTS FOR PREDICTING METHANE EMISSIONS INTENSITY

(71) Applicant: Honeywell International Inc., Charlotte, NC (US)

(72) Inventors: Shahrul Azman Bin Zainal Abidin, Kuala Lumpur (MY); Madhukar Madhavamurthy Gundappa, Bangalore (IN); Ramesh Murugan Natarajan, Bangalore (IN)

(21) Appl. No.: 18/176,763

(22) Filed: Mar. 1, 2023

(30) Foreign Application Priority Data
Dec. 20, 2022 (IN) 202211073906

(51) Int. Cl. G06F 30/27

(52) U.S. Cl. CPC G06F 30/27

(57) ABSTRACT

Methods, apparatuses, and computer program products for predicting methane emissions intensity are provided. For example, a computer-implemented method may include receiving projected production parameters and emissions reduction strategy information associated with one or more operational systems for a period of time and generating, using a methane emissions intensity prediction model, methane emissions intensity predictions based on the projected production parameters and the emissions reduction strategy information along with historical operational data and historical emissions data for the one or more operational systems. The methane emissions intensity prediction model may be a machine learning model trained on the historical operational data and historical emissions data and possibly simulated emissions data.

### CROSS-REFERENCE TO RELATED APPLICATIONS

The present application claims priority to Indian Application No. 202211073906, filed Dec. 20, 2022, the contents of which are hereby incorporated herein in their entirety by reference.

### TECHNICAL FIELD

Embodiments of the present disclosure generally relate to managing emissions in operational systems, and specifically to predicting methane emissions intensity.

### BACKGROUND

Applicant has identified many technical challenges and difficulties associated with current solutions for managing emissions in operational systems. Through applied effort, ingenuity, and innovation, Applicant has solved problems relating to managing emissions in operational systems, which are described in detail below.

### BRIEF SUMMARY

According to one aspect, embodiments of the present invention feature an apparatus comprising at least one processor and at least one non-transitory memory comprising program code stored thereon. The at least one non-transitory memory and the program code are configured to, with the at least one processor, cause the apparatus to at least receive one or more projected production parameters and emissions reduction strategy information corresponding to one or more operational systems and a period of time and generate, using a methane emissions intensity prediction model, a methane emissions intensity prediction corresponding to the one or more operational systems and the period of time based at least in part on the one or more projected production parameters, the emissions reduction strategy information, historical operational data associated with the one or more operational systems, and historical emissions data associated with the one or more operational systems. The one or more projected production parameters correspond to planned operation of the one or more operational systems in the period of time, and the emissions reduction strategy information indicates one or more planned methane emissions reduction strategies to be implemented with respect to the one or more operational systems in the period of time.

In some embodiments, the methane emissions intensity prediction model comprises a machine learning model trained based at least in part on the historical operational data and the historical emissions data.

In some embodiments, the one or more projected production parameters include planned operating conditions, planned operating capacity, and/or planned operating modes of the one or more operational systems during the period of time.

In some embodiments, the historical operational data indicates historical production parameters corresponding to past operation of the one or more operational systems. The historical production parameters might include past operating conditions, past operating capacity, and/or past operating modes of the one or more operational systems during the past operation of the one or more operational systems, and the historical emissions data might indicate methane emissions produced by the one or more operational systems and measured by emissions sensors during the past operation of the one or more operational systems. Here, the methane emissions intensity prediction is generated based at least in part on correlations between the methane emissions of the historical emissions data and the historical production parameters of the historical operational data.

In some embodiments, the methane emissions intensity prediction is generated based at least in part on simulated emissions data associated with the one or more operational systems, the simulated emissions data indicating estimated methane emissions corresponding to simulated production parameters associated with the one or more operational systems. Here, the methane emissions intensity prediction might be generated based at least in part on correlations between the estimated methane emissions and the simulated production parameters, and the methane emissions intensity prediction model might comprise a machine learning model trained based at least in part on the simulated emissions data.

According to another aspect, embodiments of the present invention feature a method comprising receiving one or more projected production parameters and emissions reduction strategy information associated with one or more operational systems and corresponding to a period of time and generating, using a methane emissions intensity prediction model, a methane emissions intensity prediction corresponding to the one or more operational systems and the period of time based at least in part on the one or more projected production parameters, the emissions reduction strategy information, historical operational data associated with the one or more operational systems, and historical emissions data associated with the one or more operational systems. The one or more projected production parameters correspond to planned operation of the one or more operational systems in the period of time, and the emissions reduction strategy information indicates one or more planned methane emissions reduction strategies to be implemented with respect to the one or more operational systems in the period of time.

According to another aspect, embodiments of the present invention feature a computer program product comprising at least one non-transitory computer-readable storage medium having computer-readable program code portions stored therein. The computer-readable program code portions comprise an executable portion configured to: receive one or more projected production parameters and emissions reduction strategy information associated with one or more operational systems and corresponding to a period of time and generate, using a methane emissions intensity prediction model, a methane emissions intensity prediction corresponding to the one or more operational systems and the period of time based at least in part on the one or more projected production parameters, the emissions reduction strategy information, historical operational data associated with the one or more operational systems, and historical emissions data associated with the one or more operational systems. The one or more projected production parameters correspond to planned operation of the one or more operational systems in the period of time, and the emissions reduction strategy information indicates one or more planned methane emissions reduction strategies to be implemented with respect to the one or more operational systems in the period of time.

The above summary is provided merely for the purpose of summarizing some example embodiments to provide a basic understanding of some aspects of the present disclosure. Accordingly, it will be appreciated that the above-described embodiments are merely examples and should not be construed to narrow the scope or spirit of the present disclosure in any way. It will be appreciated that the scope of the present disclosure encompasses many potential embodiments in addition to those here summarized, some of which will be further described below. Other features, aspects, and advantages of the subject will become apparent from the description, the drawings, and the claims.

### BRIEF DESCRIPTION OF THE DRAWINGS

Having thus described the embodiments of the disclosure in general terms, reference now will be made to the accompanying drawings, which are not necessarily drawn to scale, and wherein:

FIG. 1 illustrates an exemplary block diagram of an environment in which embodiments of the present disclosure may operate;

FIG. 2 illustrates an exemplary block diagram of an example apparatus that may be specially configured in accordance with an example embodiment of the present disclosure;

FIG. 3 illustrates a visualization of an example computing environment for generating methane emissions intensity predictions using a methane emissions intensity prediction model, in accordance with at least some example embodiments of the present disclosure;

FIG. 4 illustrates a flowchart including operational blocks of an example process for generating methane emissions intensity predictions and performing various actions based on the generated predictions, in accordance with at least some example embodiments of the present disclosure; and

FIG. 5 is an illustration of an exemplary emissions management dashboard interface of a graphical user interface, in accordance with at least some example embodiments of the present disclosure.

### DETAILED DESCRIPTION

Some embodiments of the present disclosure now will be described more fully hereinafter with reference to the accompanying drawings, in which some, but not all, embodiments of the disclosure are shown. Indeed, embodiments of the disclosure may be embodied in many different forms and should not be construed as limited to the embodiments set forth herein, rather, these embodiments are provided so that this disclosure will satisfy applicable legal requirements. Like numbers refer to like elements throughout.

As used herein, terms such as “front,” “rear,” “top,” etc. are used for explanatory purposes in the examples provided below to describe the relative position of certain components or portions of components. Furthermore, as would be evident to one of ordinary skill in the art in light of the present disclosure, the terms “substantially” and “approximately” indicate that the referenced element or associated description is accurate to within applicable engineering tolerances.

As used herein, the term “comprising” means including but not limited to and should be interpreted in the manner it is typically used in the patent context. Use of broader terms such as comprises, includes, and having should be understood to provide support for narrower terms such as consisting of, consisting essentially of, and comprised substantially of.

The phrases “in one embodiment,” “according to one embodiment,” “in some embodiments,” and the like generally mean that the particular feature, structure, or characteristic following the phrase may be included in at least one embodiment of the present disclosure, and may be included in more than one embodiment of the present disclosure (importantly, such phrases do not necessarily refer to the same embodiment).

The word “example” or “exemplary” is used herein to mean “serving as an example, instance, or illustration.” Any implementation described herein as “exemplary” is not necessarily to be construed as preferred or advantageous over other implementations.

If the specification states a component or feature “may,” “can,” “could,” “should,” “would,” “preferably,” “possibly,” “typically,” “optionally,” “for example,” “often,” or “might” (or other such language) be included or have a characteristic, that a specific component or feature is not required to be included or to have the characteristic. Such a component or feature may be optionally included in some embodiments, or it may be excluded.

The use of the term “circuitry” as used herein with respect to components of a system or an apparatus should be understood to include particular hardware configured to perform the functions associated with the particular circuitry as described herein. The term “circuitry” should be understood broadly to include hardware and, in some embodiments, software for configuring the hardware. For example, in some embodiments, “circuitry” may include processing circuitry, communication circuitry, input/output circuitry, and the like. In some embodiments, other elements may provide or supplement the functionality of particular circuitry. Alternatively or additionally, in some embodiments, other elements of a system and/or apparatus described herein may provide or supplement the functionality of another particular set of circuitry. For example, a processor may provide processing functionality to any of the sets of circuitry, a memory may provide storage functionality to any of the sets of circuitry, communications circuitry may provide network interface functionality to any of the sets of circuitry, and/or the like.

The term “electronically coupled,” “electronically coupling,” “electronically couple,” “in communication with,” “in electronic communication with,” or “connected” in the present disclosure refers to two or more elements or components being connected through wired means and/or wireless means, such that signals, electrical voltage/current, data and/or information may be transmitted to and/or received from these elements or components.

For a variety of reasons, businesses may need to track emissions of greenhouse gases (GHGs) that occur during commercial/industrial activities, such as oil and natural gas production, heating, electricity generation, and manufacturing. Such greenhouse gases include, but are not limited to carbon dioxide, nitrous oxide, and methane.

Methane emissions intensity is a key performance indicator (KPI) used by many businesses to track methane emissions and often mandated by regulations. Methane emissions intensity can be calculated at various levels ranging from an enterprise level (e.g., across an entire organization) to an individual asset level. The methane emissions intensity is generally calculated based on total methane emissions and total production. For example, for an operational system such as an operating plant, the methane emissions intensity may be calculated as a total amount of methane emissions produced by the operational system divided by a total amount (e.g., in mass) of a product or material produced by the operational system. The methane emissions intensity may be associated with a particular period of time, in which case the total amount of methane emissions within that particular period of time and the total amount of product or material produced within the same period of time may be used to determine the intensity.

It would be desirable to accurately predict the methane emissions intensity for a given future period of time. For example, a methane emissions intensity prediction would allow a business to confirm in real time whether it is on track to meet targeted emissions reduction goals. Moreover, precise determination of predicted methane emissions intensity at the level of individual assets, sites, and/or regions would provide such a business with detailed information about contributions made by the respective assets, sites, and/or regions to a predicted methane emissions intensity for an entire enterprise.

Various embodiments of the present disclosure provide for generating accurate and precise methane emissions intensity predictions to enable more accurate and timely tracking of methane emissions and methane emission reduction measures. In example embodiments, methane emissions intensity predictions are generated based on historical data describing how a system or plant has operated in the past, past emissions levels (e.g., measured by sensors) for the system or plant, and projected production parameters for determining and/or describing how a plant or operational system will be operated for a given period of time. In one example, historical methane emissions measurements corresponding to past operation of a system under certain operating conditions and/or production parameters may be used to predict methane emissions and methane emissions intensity for current or future operation of the same system under the same operating conditions and/or production parameters. Moreover, various embodiments of the present disclosure provide for generating simulated emissions data (e.g., based on simulated production parameters and/or simulated operating conditions), which can be used to generate accurate methane emissions intensity predictions in situations where projected production parameters for current or future production do not match any of those indicated in the historical data. Planned methane emissions reduction strategies for the given period of time may also be used to generate the predictions, allowing for more accurate predictions that account for expected future changes in methane emissions.

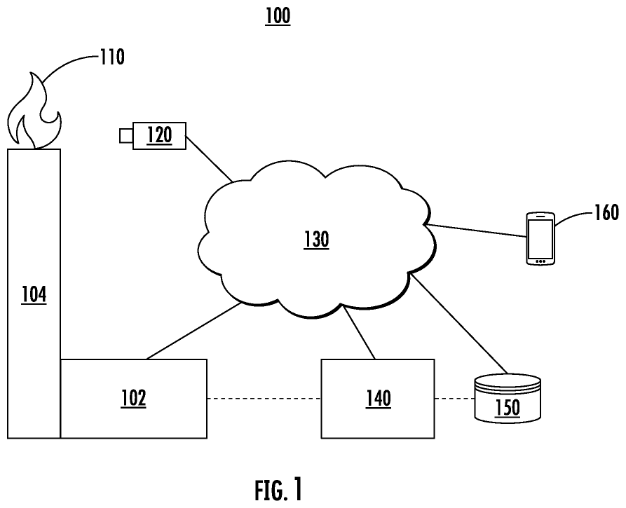

FIG. 1 illustrates an exemplary block diagram of an environment 100 in which embodiments of the present disclosure may operate. Specifically, FIG. 1 illustrates an operational system 102, which, for the purposes of illustration is depicted as a plant that may be associated with a flare stack 104 (“stack 104”). The stack 104 may be used to flare and/or vent one or more gases. These gases may include, but are not limited to, greenhouse gases. Flaring of gases may generate a flame 110. The flame 110 of a stack 104 may be observed, measured, analyzed by, and/or the like by one or more sensors 120 in accordance with operations and/or functions described herein. One or more sensors 120 may generate and/or transmit sensor data across a network 130 to an operations processing system 140. The operations processing system 140 may be electronically and/or communicatively coupled to one or more operational systems, for example one or more of the operational system 102, one or more databases 150, and one or more user devices 160. In some embodiments, the operational system 102 embodies or includes a different type of processing plant, and/or does not include the flare stack 104. For example, in some embodiments, the operational system 102 includes any number of processing units that each perform different tasks for producing a final product (e.g., a blended, constructed, or otherwise combined product) from one or more input ingredients.

The operational system 102 may, for example, be a processing plant that receives and processes ingredients as inputs to create a final product, such as a hydrocarbon processing plant. The operational system 102 may generate waste gasses. In various embodiments, waste gasses may be released to atmosphere, such as through a stack 104. Alternatively, waste gases may be flared when being released to atmosphere. Additionally, or alternatively, flaring and venting of gases may occur at locations other than a stack 104. For example, smaller quantities of gases at other locations may be released or may unintentionally leak into the atmosphere. In some embodiments, locations other than a stack 104 where gases may be vented and/or flared and/or where gases may unintentionally leak may include well heads, safety release valves, pipe headers, and/or the like.

The operational system 102 in some embodiments includes any number of individual processing units. The processing units may each embody an asset of the operational system 102 that performs a particular function during operation of the operational system 102. For example in the example context of a particular oil refinery embodying the operational system 102, the processing units may include a crude processing unit, a hydrotreating unit, an isomerization unit, a vapor recovery unit, a catalytic cracking unit, a aromatics reduction unit, a visbreaker unit, a storage tank, a blender, and/or the like that perform a particular operation for transforming, storing, and/or otherwise handling one or more input ingredient(s). In some embodiments, each individual unit embodying a component of the operational system 102 is associated with a determinable location. The determinable location of a particular unit in some embodiments represents an absolute position (e.g., GPS coordinates, latitude and longitude locations, and/or the like) or a relative position (e.g., a point representation of the location of a unit from a local origin point corresponding to the operational system 102). In some embodiments, a unit includes or otherwise is associated with a location sensor and/or software-driven location services that provide the location data representing the location corresponding to that unit. In other embodiments the location of a unit is stored and/or otherwise predetermined within a software environment, provided by a user and/or otherwise determinable to one or more systems, for example including the operations processing system 140.

Additionally or alternatively, in some embodiments, the operational system 102 itself is associated with a determinable location. The determinable location of the operational system 102 in some embodiments represents an absolute position (e.g., GPS coordinates, latitude and longitude locations, an address, and/or the like) or a relative position of the plant (e.g., an identifier representing the location of the operational system 102 as compared to one or more other plants, an enterprise headquarters, or general description in the world for example based at least in part on continent, state, or other definable region). In some embodiments, the operational system 102 includes or otherwise is associated with a location sensor and/or software-driven location services that provide the location data corresponding to the operational system 102. In other embodiments, the location of the operational system 102 is stored and/or otherwise determinable to one or more systems, for example including the operations processing system 140.

The flame 110 may be associated with flaring. Flaring involves the igniting and burning of concentrations of flammable gases. A gas may be comprised of a plurality of concentrations of individual gases, and some of these concentrations of individual gases may be flammable. Alternatively, a gas may be comprised of a concentration of an individual gas, which may or may not be flammable. In some embodiments, a gas may contain greenhouse gases, such as hydrocarbons. The hydrocarbons may be ignited by an ignition source, such as a pilot flame, when the gas passes by the ignition source. The ignited gas(es) may be referred to as flares, and this process may be referred to as flaring. In various embodiments, flaring may occur at the flare stack 104, which may be at a high level of elevation from one or more other components of a operational system 102, process area, piping, and the like associated with a site.

In embodiments with gases comprising hydrocarbons, the flaring of hydrocarbons will include lower emissions than the venting of the same gas(es). This is because flaring converts the hydrocarbons in the gas(es) to CO₂ and water while venting does not change the composition of the waste gas to water. Thus the flaring may reduce the emissions of hydrocarbons into the atmosphere. In contrast to flaring, venting does not use combustion and, instead, is a direct release of gas(es) to the atmosphere. While FIG. 1 illustrates a flame 110, it will also be appreciated that by removing or omitting an ignition source, such as a pilot flame, gas(es) may be vented without flaring.

The one or more sensors 120 may include sensors to detect, measure, and/or analyze data associated with operation of one or more plant(s), for example the operational system 102. In one such example context, the sensors detect, measure, and/or analyze a flame 110 and/or a gas emission, for example associated with a flaring, a venting, and/or an unintentional leaking. In some embodiments, sensors may include a camera, which may be configured to capture images and/or video in one or more spectrums of light. For example, a camera may be configured to capture images and/or video in the visible spectrum. Additional, and/or alternatively, a camera may be configured to capture images and/or video in the infrared spectrum. It will be appreciated that any number of sensor(s), sensor type(s), and/or the like may be utilized to monitor operations of a particular plant, and/or multiple plant(s). For example, the operational system 102 may comprise one or more sensors 120 for detecting various operating conditions of the operational system 102 and/or generating operating conditions data indicative of the detected operating conditions.

In some embodiments, a sensor of the sensors 120 (e.g., a camera) may be configured to perform or execute one or more operations and/or functions with determining a type, quantity, and/or volume of gas flared and/or emitted. For example, a camera may capture both visible light and infrared light to generate images and/or video of flaring. Based on these images and/or video of flaring, the camera may determine a type of gas being in a flame 110 as well as a volume of gas flared. In another example with a gas emission that is vented and/or leaked and not flared, a camera may capture both visible light and infrared light to generate images and/or video of venting and/or leaking. Based on these images and/or video of venting, the camera may determine a type of gas being in a flame 110 as well as a volume of gas vented and/or leaked. In various embodiments, a sensor of the sensors 120 may generate sensor data (e.g., a camera generating images and/or video) and transmit the sensor data over a network 130. In one example, the operational system 102 may comprise one or more sensors 120 for measuring methane emissions and generating emissions data indicating the emissions measurements.

The network 130 may be embodied in any of a myriad of network configurations. In some embodiments, the network 130 may be a public network (e.g., the Internet). In some embodiments, the network 130 may be a private a private network (e.g., an internal localized, or closed-off network between particular devices). In some other embodiments, the network 130 may be a hybrid network (e.g., a network enabling internal communications between particular connected devices and external communications with other devices). In various embodiments, the network 130 may include one or more base station(s), relay(s), router(s), switch(es), cell tower(s), communications cable(s), routing station(s), and/or the like. In various embodiments, components of the environment 100 may be communicatively coupled to transmit data to and/or receive data from one another over the network 130. Such configuration(s) include, without limitation, a wired or wireless Personal Area Network (PAN), Local Area Network (LAN), Metropolitan Area Network (MAN), Wide Area Network (WAN), and/or the like.

The operations processing system 140 may be located remotely or in proximity of a particular plant, for example the operational system 102. In this regard, in some embodiments, the operations processing system 140 may be located remotely or in proximity to the emissions sources, such as flame 110. In some embodiments, the operations processing system 140 is configured via hardware, software, firmware, and/or a combination thereof, to perform data intake of one or more types of data associated with one or more plant(s), for example the operational system 102. Additionally or alternatively, in some embodiments, the operations processing system 140 is configured via hardware, software, firmware, and/or a combination thereof, to generate and/or transmit command(s) that control, adjust, or otherwise impact operations of a particular plant or specific component(s) thereof, for example for controlling one or more operations of the operational system 102. Additionally or alternatively still, in some embodiments, the operations processing system 140 is configured via hardware, software, firmware, and/or a combination thereof, to perform data reporting and/or other data output process(es) associated with monitoring or otherwise analyzing operations of one or more processing plant(s), for example for generating and/or outputting report(s) corresponding to the operations performed via the operational system 102. For example, in various embodiments, the operations processing system 140 may be configured to execute and/or perform one or more operations and/or functions described herein.

The one or more databases 150 may be configured to receive, store, and/or transmit data. In some embodiments, the one or more databases 150 store data associated with multiple individual plant(s), for example multiple plants associated with the same enterprise entity but located in different geographic locations across the world. In various embodiments, the one or more databases 150 may be associated with and/or configured to store historical, current (e.g., real-time), and/or planned or projected (e.g., for the future) operational data (e.g., including sensor data, operating conditions data, operating capacity data, and/or operating mode data) for one or more operational system 102, emissions data, simulated data (e.g., including simulated emissions and/or simulated operational data), production parameters, and/or emissions reduction strategy information.

The one or more user devices 160 may be associated with users of the operations processing system 140. In various embodiments, the operations processing system 140 may generate and/or transmit a message, alert, or indication to a user via a user device, for example a user device of the user devices 160. Additionally, or alternatively, a user device, for example a user device of the user devices 160, may be utilized by a user to remotely access a operations processing system 140. This may be by, for example, an application operating on the user device, for example a user device of the user devices 160. A user may access the operations processing system 140 remotely, including one or more visualizations, reports, and/or real-time displays.

Additionally, while FIG. 1 illustrates certain components as separate, standalone entities communicating over the network 130, various embodiments are not limited to this configuration. In other embodiments, one or more components may be directly connected and/or share hardware or the like. For example, in some embodiments, the operations processing system 140 may include one or more databases 150, which may collectively be located in or at the operational system 102.

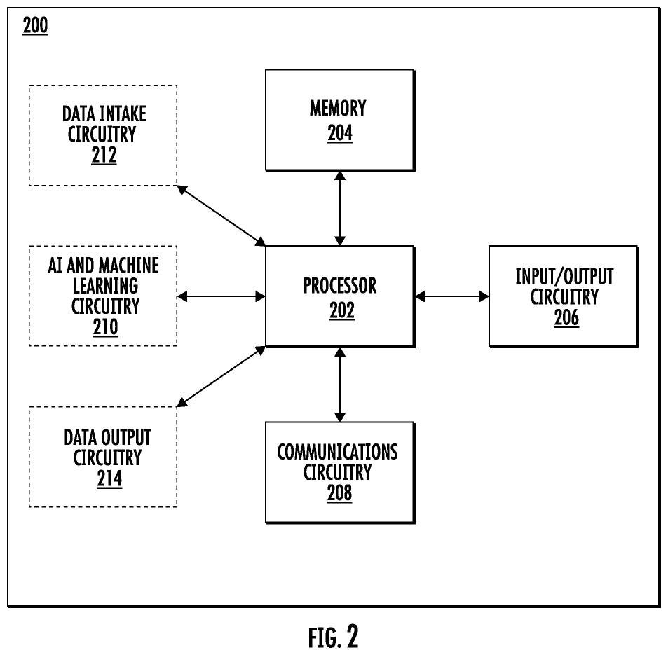

FIG. 2 illustrates an exemplary block diagram of an example apparatus that may be specially configured in accordance with an example embodiment of the present disclosure. Specifically, FIG. 2 depicts an example computing apparatus 200 (“apparatus 200”) specially configured in accordance with at least some example embodiments of the present disclosure. Examples of an apparatus 200 may include, but is not limited to, a sensor of the sensors 120, an operations processing system 140, databases 150, and/or a user device, for example a user device of the user devices 160. The apparatus 200 includes processor 202, memory 204, input/output circuitry 206, communications circuitry 208, and/or optional artificial intelligence (“AI”) and machine learning circuitry 210. In some embodiments, the apparatus 200 is configured to execute and perform the operations described herein.

Although components are described with respect to functional limitations, it should be understood that the particular implementations necessarily include the use of particular computing hardware. It should also be understood that in some embodiments certain of the components described herein include similar or common hardware. For example, in some embodiments two sets of circuitry both leverage use of the same processor(s), memory(ies), circuitry(ies), and/or the like to perform their associated functions such that duplicate hardware is not required for each set of circuitry.

In various embodiments, a device, system, or apparatus, such as apparatus 200 of an operations processing system 140 or of a user device, for example a user device of the user devices 160, may refer to, for example, one or more computers, computing entities, desktop computers, mobile phones, tablets, phablets, notebooks, laptops, distributed systems, servers, or the like, and/or any combination of devices or entities adapted to perform the functions, operations, and/or processes described herein. Such functions, operations, and/or processes may include, for example, transmitting, receiving, operating on, processing, displaying, storing, determining, creating/generating, monitoring, evaluating, comparing, and/or similar terms used herein. In one embodiment, these functions, operations, and/or processes can be performed on data, content, information, and/or similar terms used herein. In this regard, the apparatus 200 embodies a particular, specially configured computing entity transformed to enable the specific operations described herein and provide the specific advantages associated therewith, as described herein.

Processor 202 or processor circuitry 202 may be embodied in a number of different ways. In various embodiments, the use of the terms “processor” should be understood to include a single core processor, a multi-core processor, multiple processors internal to the apparatus 200, and/or one or more remote or “cloud” processor(s) external to the apparatus 200. In some example embodiments, processor 202 may include one or more processing devices configured to perform independently. Alternatively, or additionally, processor 202 may include one or more processor(s) configured in tandem via a bus to enable independent execution of operations, instructions, pipelining, and/or multithreading.

In an example embodiment, the processor 202 may be configured to execute instructions stored in the memory 204 or otherwise accessible to the processor. Alternatively, or additionally, the processor 202 may be configured to execute hard-coded functionality. As such, whether configured by hardware or software methods, or by a combination thereof, processor 202 may represent an entity (e.g., physically embodied in circuitry) capable of performing operations according to embodiments of the present disclosure while configured accordingly. Alternatively, or additionally, processor 202 may be embodied as an executor of software instructions, and the instructions may specifically configure the processor 202 to perform the various algorithms embodied in one or more operations described herein when such instructions are executed. In some embodiments, the processor 202 includes hardware, software, firmware, and/or a combination thereof that performs one or more operations described herein.

In some embodiments, the processor 202 (and/or co-processor or any other processing circuitry assisting or otherwise associated with the processor) is/are in communication with the memory 204 via a bus for passing information among components of the apparatus 200.

Memory 204 or memory circuitry embodying the memory 204 may be non-transitory and may include, for example, one or more volatile and/or non-volatile memories. In some embodiments, the memory 204 includes or embodies an electronic storage device (e.g., a computer readable storage medium). In some embodiments, the memory 204 is configured to store information, data, content, applications, instructions, or the like, for enabling an apparatus 200 to carry out various operations and/or functions in accordance with example embodiments of the present disclosure.

Input/output circuitry 206 may be included in the apparatus 200. In some embodiments, input/output circuitry 206 may provide output to the user and/or receive input from a user. The input/output circuitry 206 may be in communication with the processor 202 to provide such functionality. The input/output circuitry 206 may comprise one or more user interface(s). In some embodiments, a user interface may include a display that comprises the interface(s) rendered as a web user interface, an application user interface, a user device, a backend system, or the like. In some embodiments, the input/output circuitry 206 also includes a keyboard, a mouse, a joystick, a touch screen, touch areas, soft keys a microphone, a speaker, or other input/output mechanisms. The processor 202 and/or input/output circuitry 206 comprising the processor may be configured to control one or more operations and/or functions of one or more user interface elements through computer program instructions (e.g., software and/or firmware) stored on a memory accessible to the processor (e.g., memory 204, and/or the like). In some embodiments, the input/output circuitry 206 includes or utilizes a user-facing application to provide input/output functionality to a computing device and/or other display associated with a user.

Communications circuitry 208 may be included in the apparatus 200. The communications circuitry 208 may include any means such as a device or circuitry embodied in either hardware or a combination of hardware and software that is configured to receive and/or transmit data from/to a network and/or any other device, circuitry, or module in communication with the apparatus 200. In some embodiments the communications circuitry 208 includes, for example, a network interface for enabling communications with a wired or wireless communications network. Additionally or alternatively, the communications circuitry 208 may include one or more network interface card(s), antenna(s), bus(es), switch(es), router(s), modem(s), and supporting hardware, firmware, and/or software, or any other device suitable for enabling communications via one or more communications network(s). In some embodiments, the communications circuitry 208 may include circuitry for interacting with an antenna(s) and/or other hardware or software to cause transmission of signals via the antenna(s) and/or to handle receipt of signals received via the antenna(s). In some embodiments, the communications circuitry 208 enables transmission to and/or receipt of data from a user device, one or more sensors, and/or other external computing device(s) in communication with the apparatus 200.

Data intake circuitry 212 may be included in the apparatus 200. The data intake circuitry 212 may include hardware, software, firmware, and/or a combination thereof, designed and/or configured to capture, receive, request, and/or otherwise gather data associated with operations of one or more operational systems (e.g., plants). In some embodiments, the data intake circuitry 212 includes hardware, software, firmware, and/or a combination thereof, that communicates with one or more sensor(s), unit(s), and/or the like within a particular plant to receive particular data associated with such operations of the plant. The data intake circuitry 212 may support such operations for any number of individual plants. Additionally or alternatively, in some embodiments, the data intake circuitry 212 includes hardware, software, firmware, and/or a combination thereof, that retrieves particular data associated with one more more plant(s) from one or more data repository/repositories accessible to the apparatus 200.

AI and machine learning circuitry 210 may be included in the apparatus 200. The AI and machine learning circuitry 210 may include hardware, software, firmware, and/or a combination thereof designed and/or configured to request, receive, process, generate, and transmit data, data structures, control signals, and electronic information for training and executing a trained AI and machine learning model configured to facilitating the operations and/or functionalities described herein. For example, in some embodiments the AI and machine learning circuitry 210 includes hardware, software, firmware, and/or a combination thereof, that identifies training data and/or utilizes such training data for training a particular machine learning model, AI, and/or other model to generate particular output data based at least in part on learnings from the training data. Additionally or alternatively, in some embodiments, the AI and machine learning circuitry 210 includes hardware, software, firmware, and/or a combination thereof, that embodies or retrieves a trained machine learning model, AI and/or other specially configured model utilized to process inputted data. Additionally or alternatively, in some embodiments, the AI and machine learning circuitry 210 includes hardware, software, firmware, and/or a combination thereof that processes received data utilizing one or more algorithm(s), function(s), subroutine(s), and/or the like, in one or more pre-processing and/or subsequent operations that need not utilize a machine learning or AI model.

Data output circuitry 214 may be included in the apparatus 200. The data output circuitry 214 may include hardware, software, firmware, and/or a combination thereof, that configures and/or generates an output based at least in part on data processed by the apparatus 200. In some embodiments, the data output circuitry 214 includes hardware, software, firmware, and/or a combination thereof, that generates a particular report based at least in part on the processed data, for example where the report is generated based at least in part on a particular reporting protocol. Additionally or alternatively, in some embodiments, the data output circuitry 214 includes hardware, software, firmware, and/or a combination thereof, that configures a particular output data object, output data file, and/or user interface for storing, transmitting, and/or displaying. For example, in some embodiments, the data output circuitry 214 generates and/or specially configures a particular data output for transmission to another sub-system for further processing. Additionally or alternatively, in some embodiments, the data output circuitry 214 includes hardware, software, firmware, and/or a combination thereof, that causes rendering of a specially configured user interface based at least in part on data received by and/or processing by the apparatus 200.

In some embodiments, two or more of the sets of circuitries 202-214 are combinable. Alternatively, or additionally, one or more of the sets of circuitry 202-214 perform some or all of the operations and/or functionality described herein as being associated with another circuitry. In some embodiments, two or more of the sets of circuitry 202-214 are combined into a single module embodied in hardware, software, firmware, and/or a combination thereof. For example, in some embodiments, one or more of the sets of circuitry, for example the AI and machine learning circuitry 210, may be combined with the processor 202, such that the processor 202 performs one or more of the operations described herein with respect the AI and machine learning circuitry 210.

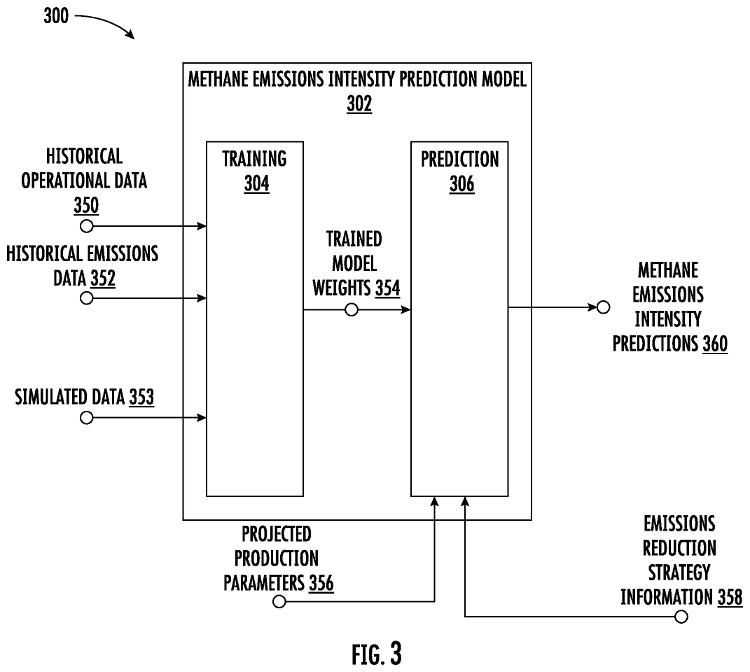

FIG. 3 illustrates a visualization of an example computing environment for generating methane emissions intensity predictions using a methane emissions intensity prediction model, in accordance with at least some example embodiments of the present disclosure. In this regard, the example computing environments and various data described associated therewith may be maintained by one or more computing devices, such as the operations processing system 140 and/or the apparatus 200. The operations processing system 140 and/or the apparatus 200, for example, may be specially configured via hardware, software, firmware, and/or a combination thereof, to perform the various data processing and interactions described with respect to FIG. 3 to generate methane emissions intensity predictions.

In various embodiments, the operations processing system 140 and/or the apparatus 200 may be configured to generate a methane emissions intensity prediction (e.g., using a methane emissions intensity prediction model) for an operational system 102.

The example computing environment 300 of FIG. 3 comprises a methane emissions intensity prediction model 302 for generating one or more methane emissions intensity prediction(s), for example embodied in one or more methane emissions intensity predictions 360. In an example embodiment, a methane emissions intensity prediction model 302 uses historical and/or simulated data to generate the prediction for one or more planned or projected production parameters and/or planned emissions reduction strategies.

In the illustrated example, the methane emissions intensity prediction model 302 is configured based at least in part on a training process 304 and a prediction process 306.

In various embodiments, the methane emissions intensity prediction model 302 may undergo a training process (e.g., represented by the training process 304) using a training data set in order to identify features and to determine optimal coefficients representing adjustment or weights to apply with respect to the features in order to produce a target methane emissions intensity reflected in the training data set, for example, based on positive and/or negative correlations between extracted features from the historical operational data 350 and extracted features from the historical emissions data 352 (e.g., historical emissions measurements, methane emissions intensities calculated from the historical data). The methane emissions intensity prediction model 302 may comprise a data object created by using machine learning to learn to perform a given function (e.g., a prediction) through training with the training data set. For example, the training process may formulate a mapping function ffrom input variables x to discrete output variables y. The methane emissions intensity prediction model 302 may be trained to generate a methane emissions intensity prediction, for example embodied in the methane emissions intensity predictions 360, by learning from the training data set.

In some embodiments (not illustrated), the methane emissions intensity prediction model may comprise one or more specially designed algorithms for generating methane emissions intensity predictions based at least in part on historical operational data, historical emissions data, simulated data, projected production parameters, and emissions reduction strategy information. For example, the one or more specially designed algorithms may be configured to determine an estimated rate of methane emissions and production parameters corresponding to the projected production parameters based at least in part on the historical operational data, the historical emissions data, and/or the simulated data (e.g., via regression analysis), calculate estimated total methane emissions and estimated total production for a given period of time based at least in part on the determined estimated rate of methane emissions and the determined estimated rate of production, calculate a predicted methane emissions intensity based at least in part on the estimated total methane emissions and estimated total production, and generate the methane emissions intensity prediction based at least in part on the predicted methane emissions intensity (e.g., the prediction including the calculated predicted methane emissions intensity).

In the illustrated example, the training data set input into the methane emissions intensity prediction model 302 at the training process 304 comprises historical data for the operational system 102, including historical operational data 350 and/or historical emissions data 352, and/or simulated data 353, including simulated operational data and/or simulated emissions data.

In general, operational data for an operational system 102 may indicate various properties, detected conditions, user-configured settings, parameters, outputs, and/or measurements corresponding to operation of the operational systems, for example one or more of the operational system 102. Operational data may include historical operational data 350 corresponding to past and current operation of the operational system 102. Operational data may also include projected or planned operational data corresponding to planned or future operation of the operational system 102. Operational data may include preconfigured, calculated, and/or user inputted data associated with operation of an operational system 102, including historical, current, and/or projected production parameters. Operational data may include sensor data received via sensors 120 and indicative of various conditions and/or values detected and/or measured during past and/or current operation of the operational system 102.

Production parameters for an operational system may refer to information and/or data for determining or describing how the operational system 102, and/or one or more particular assets associated therewith, for example assets embodying physical processing units or other components of a processing plant, operates during various periods of operation of the operational system 102. The production parameters may be user-configured and/or user inputted values and/or data objects representing desired functionality or operation of the operational system 102 and/or one or more particular assets and/or components thereof. The production parameters may determine the operation of the operational system 102 and/or one or more particular assets and/or components thereof. For example, the operations processing system 140 and/or a controller of the operational system 102 may be configured to control functionality of the operational system 102 and/or one or more particular assets and/or components thereof according to received production parameters. The production parameters may simply describe the operation of the operational system 102 and/or one or more particular assets and/or components thereof. For example, the operational system 102 and/or one or more particular assets and/or components thereof may be configured to operate according to the production parameters by means other than the production parameters themselves (e.g., electronically, mechanically, chemically, and/or the like), and the production parameters may be input, generated, and/or retained as a record to describe how the operational system 102 and/or one or more particular assets and/or components thereof is or was configured to operate during various periods of operation. The production parameters may include data indicative of operating capacity and/or operating modes of an operational system 102 and/or one or more particular assets and/or components thereof during various periods of operation.

The historical operational data 350 may comprise sensor data, including operating conditions data generated via the one or more sensors 120. The sensor data may include sensor data collected over relatively long periods of time such as one or more years as well as current sensor data (e.g., collected in real time). For example, operating conditions data of the historical operational data 350 may include a timestamp indicating an instance of time when each detection or measurement was taken along with sensor data (e.g., sensor values) indicative of the operating conditions at that instance of time such as temperature, pressure, flow rate, and/or composition of materials moving through and/or being processed within or by various components of the operational system 102 or of the components of the operational system 102 themselves, to list a few examples.

The historical operational data 350 may comprise preconfigured, calculated, and/or user inputted data associated with past operations of one or more plant(s) and/or one or more particular assets and/or components thereof, including historical and/or current production parameters. Each historical production parameter of the historical operational data 350 may describe how the operational system 102 and/or one or more particular assets and/or components thereof is or was configured to operate during periods of operation corresponding to the production parameter, including data indicative of past operating capacity and/or past operating modes of the operational system 102 and/or one or more particular assets and/or components thereof.

In one example, the historical production parameters of the historical operational data 350 may include past operating capacity, past operating modes, and/or any other historical production parameters corresponding to one or more periods of past or current operation of the operational system 102 and/or one or more particular assets and/or components thereof. These historical production parameters may be user-configured and/or user inputted (e.g., originally as projected production parameters) in order to determine how the operational system 102 and/or one or more particular assets and/or components thereof is to operate during a period of time and then retained and stored (e.g., as historical production parameters) to provide a historical record describing how the operational system 102 and/or one or more particular assets and/or components thereof operated during past operation of the operational system 102 during that period of time. The historical production parameters may be combined with, may incorporate, and/or may include references to information and/or data that is determined and/or calculated during the past operation of the operational system 102 and/or one or more particular assets and/or components thereof and then stored in association with the historical production parameters such as, for example, historical sensor data, including historical operating conditions data and/or the historical emissions data 352.

The historical emissions data 352 may comprise emissions data generated via one or more sensors 120 that are specifically emissions sensors for measuring methane emissions produced by the operational system 102 and/or one or more particular assets and/or components thereof, including individual components of the operational system 102, parts of the individual components, groups of components, and/or the operational system 102 overall. The emissions data may include emissions data collected over relatively long periods of time such as one or more years as well as current sensor data (e.g., collected in real time). In one example, the emissions data may comprise a timestamp indicating an instance of time when each measurement was taken along with attributes characterizing the emissions measurement such as emissions type, quantity, and/or volume of methane emitted at one or more components of the operational system 102 and/or for the operational system 102 as a whole.

The simulated data 353 may comprise simulated emissions data, simulated production parameters, and/or simulated operating conditions data. The simulated emissions data may indicate estimated methane emissions that would result from operation of the operational system 102 and/or one or more particular assets and/or components thereof according to one or more sets of simulated production parameters. The simulated emissions data may be generated by a simulation process configured to receive (e.g., via user input) a virtual representation of one or more operational system 102 and/or one or more particular assets and/or components thereof and simulated production parameters and, based on the received virtual representation and simulated production parameters, output simulated data representing results of operation of the operational system 102 and/or one or more particular assets and/or components thereof according to the simulated production parameters. The simulated data output by the simulation process may comprise simulated emissions data representing estimated methane emissions that would result from the operation of the operational system 102 and/or one or more particular assets and/or components thereof according to the simulated production parameters. The simulated data output by the simulation process may comprise simulated operating conditions data representing estimated operating conditions that would result from the operation of the operational system 102 and/or one or more particular assets and/or components thereof according to the simulated production parameters, such as estimated temperature, pressure, flow rate, and/or composition of materials moving through and/or being processed within or by various components of the system or of the components themselves, to list a few examples. The simulated production parameters received as input by the simulation process may be preconfigured or user-configured and/or may be selected from sets of possible production parameters associated with each operational system 102 and/or one or more particular assets and/or components thereof (and/or each virtual representation of each operational system 102 and/or one or more particular assets and/or components thereof). In various embodiments, the operations processing system 140 and/or apparatus 200 may be configured to determine a domain of possible production parameters for an operational system 102 and/or one or more particular assets and/or components thereof and/or its virtual representation and/or the virtual representation of one or more particular assets and/or components thereof, generate sets of simulated production parameters representative of an entirety of the domain of possible production parameters (e.g., evenly distributed across the domain), and execute the simulation process to generate the simulated emissions data and/or simulated operating conditions data for each of the generated sets of simulated production parameters. The apparatus may be configured to determine (e.g., from the projected production parameters) that an operational system is scheduled or planned to operate in a particular manner (e.g., according to particular parameters, in a particular mode and/or capacity), to determine (e.g., from the historical data) that the operational system has not previously operated in that particular manner, and, in response, to generate the simulated data (e.g., simulated emissions data) corresponding to and/or based on the projected production parameters in order to fill in missing data in the input and/or training data sets that may be useful or necessary for making the prediction. In one example, the operations processing system 140 and/or apparatus 200 may be configured to determine whether projected production parameters (e.g., for planned or future operation of an operational system 102 and/or one or more particular assets and/or components thereof) correspond to any historical production parameters indicated in the historical operational data 350 (e.g., for past operation of the operational system 102 and/or one or more particular assets and/or components thereof) and, in response to determining that the projected production parameters do not correspond to any historical production parameters (e.g., by virtue of the operational system 102 and/or one or more particular assets and/or components thereof never having previously operated according to the projected production parameters), execute the simulation process to generate the simulated emissions data and/or simulated operating conditions data for simulated production parameters corresponding to (e.g., matching) the projected production parameters. In various embodiments, the operations processing system 140 and/or apparatus 200 may be configured to combine and store (as the simulated data 353) each set of simulated production parameters used by the simulation process and any simulated emissions data and/or simulated operating conditions data resulting from executing the simulation process with respect to the simulated production parameters.

In one example, the training process 304 may formulate a mapping function ƒ from input variables x to discrete output variables y, with the input variables x each representing features extracted from the training data set (e.g., historical operational data 350, historical emissions data 352, simulated data 353). For example, based at least in part on the training process 304, the methane emissions intensity prediction model 302 may be configured to express a methane emissions intensity prediction using a function ƒ(x₁, x₂, . . . , xₚ), where x₁, x₂, . . . , xₚ are features, quantities, values, and/or metrics extracted, calculated, and/or determined from the training data set. In particular, the features, quantities, values, and/or metrics extracted, calculated, and/or determined from the training data set may represent and/or correspond to attributes (e.g., values, quantities) reflected in the training data set with respect to a particular data item associated with the prediction being generated such as methane emissions and/or amount of material or product produced associated with one or more particular production parameters and/or duration of time operating according to the one or more particular production parameters. The mapping function formulated via the training process 304 may be based at least in part on one or more formulas for calculating methane emissions intensity. For example, based at least in part on the training process 304, the methane emissions intensity prediction model 302 may be configured to express a methane emissions intensity prediction for one or more particular production parameters as a total amount of methane emissions produced by the operational system 102 and/or one or more particular assets and/or components thereof when operating according to the one or more particular production parameters (e.g., determined based on measurements of methane emissions indicated in the historical emissions data 352 for periods of time during which the operational system 102 and/or one or more particular assets and/or components thereof operated according to the one or more particular production parameters, determined based on estimated methane emissions indicated in the simulated data 353 for simulated operation of the operational system 102 and/or one or more particular assets and/or components thereof according to the particular production parameters) divided by a total amount of production (e.g., material or product produced) of the operational system 102 and/or one or more particular assets and/or components thereof when operating according to the one or more particular production parameters (e.g., determined based on the historical operational data 350 and/or calculated based on the particular production parameters, determined based on the simulated data 353). The training process 304 may formulate mapping functions at the level of individual assets or components of an operational system 102, an operational system 102 itself, and/or groups of operational systems, for example one or more of the operational system 102, (e.g., all operational systems, for example one or more of the operational system 102, within predefined sites, all operational systems, for example one or more of the operational system 102, for all sites within predefined geographical regions, all operational systems, for example one or more of the operational system 102, across an entire enterprise).

In some embodiments, the historical operational data 350, historical emissions data 352, and simulated data 353 are input into the training process 304 of the methane emissions intensity prediction model 302 to train the model to generate the methane emissions intensity predictions 360. A product of the model training are trained model weights 354 that are used by the prediction process 306 of the methane emissions intensity prediction model 302. In some embodiments, after an initial training, further training data (e.g., subsequently received and/or generated historical operational data 350, historical emissions data 352, simulated data 353) may be input to the training process 304 of the methane emissions intensity prediction model 302, periodically or on an on-going basis, to refine and update the model.

The methane emissions intensity prediction model 302 may be trained to generate a methane emissions intensity prediction, for example embodied in the methane emissions intensity predictions 360, based at least in part on an input data set.

In some embodiments, an input data set for generating the methane emissions intensity prediction, for example embodied in the methane emissions intensity predictions 360, may comprise one or more projected production parameters 356 and/or emissions reduction strategy information 358.

Each of the one or more projected production parameters 356 may be a production parameter for determining or describing how an operational system 102 and/or one or more particular assets and/or components thereof will or should operate during periods of planned or future operation of the operational system 102 and/or one or more particular assets and/or components thereof, including planned operating capacity, planned operating mode, planned or expected operating conditions, and/or any other planned production parameters corresponding to one or more periods of planned (e.g., future) operation of the operational system 102 and/or one or more particular assets and/or components thereof. In one example, the projected production parameters 356 may include data indicative of a period of time (e.g., duration, start time, end time) during which a period of planned operation is to occur, data indicative of operating modes in which the operational system 102 and/or one or more particular assets and/or components thereof is planned to operate during the period of time, data indicative of an operating capacity at which the operational system 102 and/or one or more particular assets and/or components thereof is planned to operate during the period of time, and/or data indicative of prescribed or expected operating conditions under which the operational system 102 and/or one or more particular assets and/or components thereof is planned to operate during the period of time. The projected production parameters 356 may be user-configured and/or user inputted or calculated based on user input.

The emissions reduction strategy information 358 may describe or indicate one or more planned methane emissions reduction strategies to be implemented for the one or more operational systems, for example one or more of the operational system 102, and/or one or more particular assets and/or components thereof, at particular periods of time. The emissions reduction strategy information may be user-configured and/or user inputted and stored in the one or more databases 150. The emissions reduction strategy information may comprise information and/or data identifying a period of time and a selected one or more planned methane emissions reduction strategies (e.g., out of a set of predetermined methane emissions reduction strategies), each of which is associated with information and/or data indicative of, describing, and/or usable to calculate or determine estimated reductions in quantity and/or volume of methane emissions resulting from implementation of the strategies. The one or more planned methane emissions reduction strategies may represent, refer to, correspond with, and/or identify actions to be taken to change the physical configuration of the operational system 102 and/or one or more particular assets and/or components thereof, actions to be taken to change how the operational system 102 and/or one or more particular assets and/or components thereof are controlled, and/or actions to be taken to change properties of materials (e.g., ingredients) to be input into and/or processed by the operational system 102 and/or one or more particular assets and/or components thereof, to list a few examples. The emissions reduction strategy information 358 may comprise data and/or information sufficient for determining estimated emissions reductions resulting from the planned methane emissions reduction strategies and/or adjusting estimated or predicted methane emissions, estimated or predicted production amount, and/or the methane emissions intensity prediction, for example embodied in the methane emissions intensity predictions 360, itself to account for estimated emissions reductions resulting from the planned methane emissions reduction strategies.

In one example, the emissions reduction strategy information 358 may identify components of the operational system 102 and/or one or more particular assets and/or components thereof that are planned to be replaced with more efficient and/or more effective components or repaired and/or modified to be more efficient and/or effective, the information including a reference to the identified components of the operational system 102 and/or one or more particular assets and/or components thereof to be replaced, repaired, and/or modified, a reference to any replacement components, and/or information and/or data concerning expected changes in efficiency and/or effectiveness of the component and/or operational system 102 resulting from the replacement, repair, and/or modification, which information and/or data can be used to calculate and/or determine an estimated reduction in quantity and/or volume of methane emissions resulting from the replacement, repair, and/or modification.

In another example, the emissions reduction strategy information may identify one or more new sources of materials (e.g., ingredients) input into and/or processed by the operational system 102 and/or one or more particular assets and/or components thereof along with information and/or data concerning methane emissions associated with providing or delivering the materials to the operational system 102 and/or one or more particular assets and/or components thereof from the new sources relative to providing or delivering the materials from original or old sources of the materials, which information and/or data can be used to calculate and/or determine an estimated reduction in quantity and/or volume of methane emissions resulting from the new sources of the materials.

In some embodiments, the one or more projected production parameters 356 and emissions reduction strategy information 358 are input into the prediction process 306 of the methane emissions intensity prediction model 302.

Upon receiving the one or more projected production parameters 356 and emissions reduction strategy information 358, the prediction process 306 of the methane emissions intensity prediction model 302 outputs the methane emissions intensity predictions 360.

In some embodiments, each methane emissions intensity prediction, for example embodied in the methane emissions intensity predictions 360, may be associated with a period of time (e.g., in the future), one or more methane emissions reduction strategies planned for implementation within the period of time, and/or a targeted methane emissions intensity (e.g., user-configured, calculated) representing a benchmark, milestone, and/or desired value for the methane emissions intensity. Thus, the methane emissions intensity prediction, for example embodied in the methane emissions intensity predictions 360, may be used not only to accurately estimate the methane emissions intensity for the period of time (e.g., in response to user input indicating a selection of the period of time) but also to track effectiveness (e.g., in real time) of the one or more methane emissions reduction strategies and/or to track progress and/or likelihood of reaching the targeted methane emissions intensity in the period of time.

In some embodiments, each methane emissions intensity prediction, for example embodied in the methane emissions intensity predictions 360, may be associated with a selection of one or more assets, components, operational systems, for example one or more of the operational system 102, sites, and/or regions covered by the prediction. Here, the methane emissions intensity prediction, for example embodied in the methane emissions intensity predictions 360, may represent the methane emissions intensity specifically with respect to the selected assets, components, operational systems, for example one or more of the operational system 102, sites, and/or regions, allowing granular tracking at the level of individual assets and/or components as well as overall tracking at the level of one or more operational systems, for example one or more of the operational system 102.

Having described example systems and/or apparatuses of the present disclosure, example flowcharts including various operations performed by the apparatuses and/or systems described herein will now be discussed. It should be appreciated that each of the flowcharts depicts an example computer-implemented process that may be performed by one or more of the apparatuses, systems, and/or devices described herein, for example utilizing one or more of the components thereof. The blocks indicating operations of each process may be arranged in any of a number of ways, as depicted and described herein. In some such embodiments, one or more blocks of any of the processes described herein occur in-between one or more blocks of another process, before one or more blocks of another process, and/or otherwise operates as a sun-process of a second process. Additionally or alternative, any of the processes may include some or all of the steps described and/or depicted, including one or more optional operational blocks in some embodiments. With respect to the flowcharts discussed below, one or more of the depicted blocks may be optional in some, or all, embodiments of the disclosure. Similarly, it should be appreciated that one or more of the operations of each flowchart may be combinable, replaceable, and/or otherwise altered as described herein.

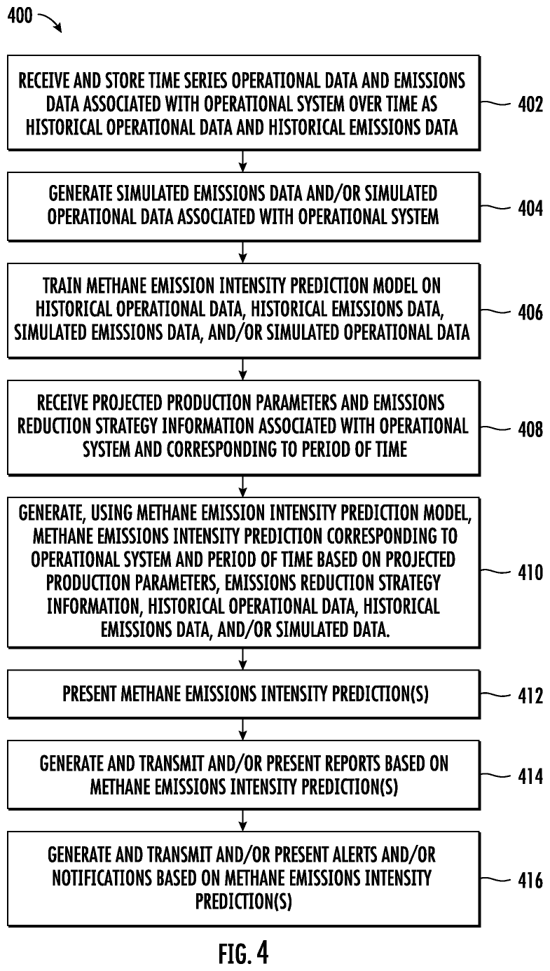

FIG. 4 illustrates a flowchart including operational blocks of an example process 400 for generating methane emissions intensity predictions 360, and performing various actions based at least in part on the generated predictions, in accordance with at least some example embodiments of the present disclosure. In some embodiments, the computer-implemented process of FIG. 4 is embodied by computer program code stored on a non-transitory computer-readable medium of a computer program product configured for execution to perform the computer-implemented method. Alternatively or additionally, in some embodiments, the example process 400 of FIG. 4 is performed by one or more specially configured computing devices, such as the specially configured apparatus 200 (e.g., via data intake circuitry 212, AI and machine learning circuitry 210, and/or data output circuitry 214). In this regard, in some such embodiments, the apparatus 200 is specially configured by computer program instructions stored thereon, for example in the memory 204 and/or another component depicted and/or described herein, and/or otherwise accessible to the apparatus 200, for performing the operations as depicted and described with respect to the example process of FIG. 4. In some embodiments, the specially configured apparatus 200 includes and/or otherwise is in communication with one or more external apparatuses, systems, devices, and/or the like, to perform one or more of the operations as depicted and described.

The process 400 begins at operation 402, at which an apparatus (such as, but not limited to, the apparatus 200 or circuitry thereof as described above in connection with FIG. 2) receives and stores operational data and emissions data associated with one or more operational systems, for example one or more of the operational system 102, such as the plant depicted in FIG. 1. In one example, the apparatus may be configured to gather, request, receive, and/or aggregate time series operational data and time series emissions data from one or more operational systems, for example one or more of the operational system 102, over a period of time and store the gathered, requested, received, and/or aggregated data as historical operational data 350 and historical emissions data 352.

At operation 404, an apparatus (such as, but not limited to, the apparatus 200 or circuitry thereof described above in connection with FIG. 2) generates simulated data 353, including simulated operational data and/or simulated emissions data. The simulated data generated at operation 404 may be the simulated data 353 defined and described with respect to FIG. 3 and may be generated in the manner previously described with respect to FIG. 3. For example, the apparatus may be configured to execute a simulation process with respect to a set of simulated production parameters, which may generate the simulated data 353 to include simulated emissions data and/or simulated operating conditions data that would result from operation of an operational system 102 according to the simulated parameters.

At operation 406, an apparatus (such as, but not limited to, the apparatus 200 or circuitry thereof described above in connection with FIG. 2) trains the methane emissions intensity prediction model 302 based at least in part on the historical operational data 350, the historical emissions data 352, and/or the simulated data 353. The apparatus may be configured to train the model in the manner described with respect to FIG. 3, including the training process 304 defined and described with respect to FIG. 3.

At operation 408, an apparatus (such as, but not limited to, the apparatus 200 or circuitry thereof described above in connection with FIG. 2) receives one or more projected production parameters 356 and emissions reduction strategy information 358 corresponding to a period of time. The one or more projected production parameters 356 and the emissions reduction strategy information 358 received at operation 408 may be that respectively defined and described with respect to FIG. 3.

At operation 410, an apparatus (such as, but not limited to, the apparatus 200 or circuitry thereof described above in connection with FIG. 2) generates, using a methane emissions intensity prediction model 302, a methane emissions intensity prediction, for example embodied in the methane emissions intensity predictions 360, corresponding to the one or more operational systems, for example one or more of the operational system 102, and the period of time based at least in part on the one or more projected production parameters 356 and the emissions reduction strategy information 358 received at operation 408, the historical operational data 350 and the historical emissions data 352 received and stored at operation 402, and/or the simulated data 353 generated at operation 404. The apparatus may be configured to generate the methane emissions intensity prediction, for example embodied in the methane emissions intensity predictions 360, using the methane emissions intensity prediction model 302 in the manner described with respect to FIG. 3, including the prediction process 306 defined and described with respect to FIG. 3.

At operation 412, an apparatus (such as, but not limited to, the apparatus 200 or circuitry thereof described above in connection with FIG. 2) presents the methane emissions intensity prediction, for example embodied in the methane emissions intensity predictions 360, generated at operation 410. In one example, the apparatus may be configured to present the prediction by causing the prediction to be displayed on a display of a computing device, for example, as part of a graphical user interface.

At operation 414, an apparatus (such as, but not limited to, the apparatus 200 or circuitry thereof described above in connection with FIG. 2) generates and transmits and/or presents reports based at least in part on the methane emissions intensity prediction, for example embodied in the methane emissions intensity predictions 360, generated at operation 410. In one example, the apparatus may be configured to receive user-configured report parameters and generate the report based at least in part on the prediction, for example embodied in the methane emissions intensity predictions 360, and the report parameters (e.g., by retrieving and/or generating a filtered set of data and generating a formatted report based at least in part on the report parameters, the filtered set of data comprising the methane emissions intensity prediction, for example embodied in the methane emissions intensity predictions 360, and selected data and/or information relevant to the prediction such as calculated estimated emissions and/or production amounts used to calculate the methane emissions intensity prediction, for example embodied in the methane emissions intensity predictions 360, and/or aggregated or individual sensor data).

At operation 416, an apparatus (such as, but not limited to, the apparatus 200 or circuitry thereof described above in connection with FIG. 2) generates and transmits and/or presents alerts and/or notifications based at least in part on the methane emissions intensity prediction, for example embodied in the methane emissions intensity predictions 360, generated at operation 410. In one example, the apparatus may be configured to periodically, continually, and/or continuously monitor methane emissions intensity predictions 360, for particular assets, components, systems, sites, regions, and/or enterprises by comparing the predictions against respective targeted methane emissions intensities associated with the particular assets, components, systems, sites, regions, and/or enterprises and generating the alerts and/or notifications in response to determining that a prediction, for example embodied in the methane emissions intensity predictions 360, does not meet or satisfy, or is on track to fail to meet or satisfy, a targeted intensity value (e.g., in response to determining that predictions 360 differ from target values by a predetermined threshold).

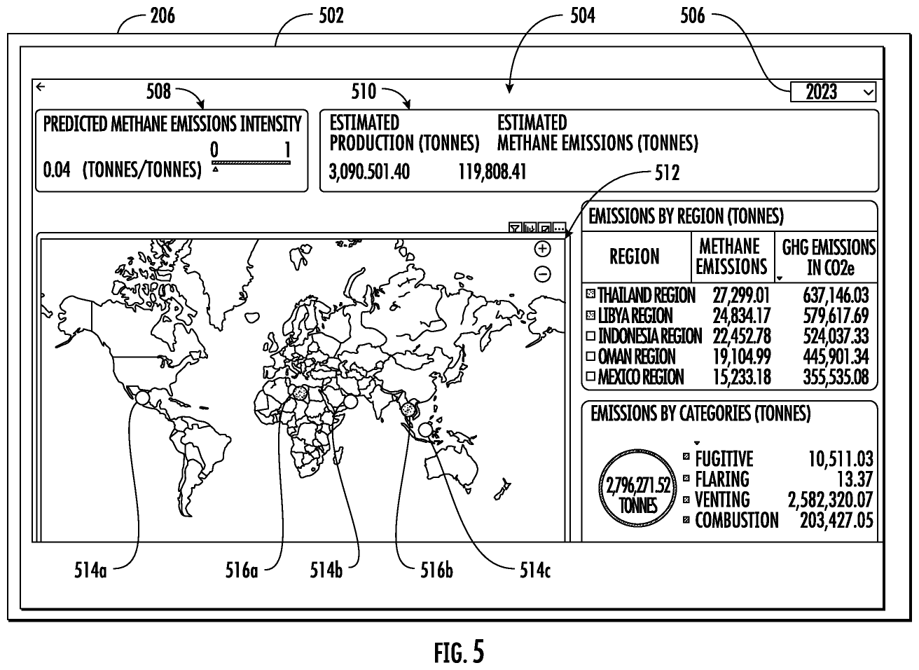

FIG. 5 is an illustration of an exemplary emissions management dashboard interface 504 of a graphical user interface (GUI) 502 presented by the apparatus 200 (e.g., via the data output circuitry 214). The emissions management dashboard interface 504, including any methane emissions intensity predictions 360, provided as part of the dashboard, may be presented at operation 412 of the process 400 depicted in FIG. 4, for example. The GUI 502 may be rendered on a display of a computing device, for example, via the input/output circuitry 206 of the apparatus 200. The emissions management dashboard interface 504 is used to present methane emissions intensity predictions 360, and other information concerning one or more operational systems, for example one or more of the operational system 102, of an enterprise. The GUI 502 comprises graphical elements arranged to form the emissions management dashboard interface 504, which may be rendered on a display. The graphical elements may include textual information, shapes, graphs, tables, icons, and/or images, provided within various panes and/or windows, to list a few examples. Some of the graphical elements may, in combination, present information concerning one or more operational systems, for example one or more of the operational system 102, and/or components or assets thereof. The graphical elements may include interface elements, which are user-interactable features of the GUI 502 for receiving user input indicating selections for changing what information is presented by the emissions management dashboard interface 504 and/or how the information is presented.

In the illustrated example, the emissions management dashboard interface 504 comprises a time selector 506, a prediction pane 508, an estimates pane 510, and a map pane 512 comprising a series of location indicators 514, 516.

The time selector 506 may be an interface element for receiving input indicative of a selected prediction period. The selected prediction period may represent a period of time for which the methane emissions intensity predictions 360, may be generated and/or displayed. In response to receiving a selected prediction period via the time selector 506, the apparatus 200 may be configured to update the emissions management dashboard interface 504 to present information specific to the selected prediction period, including causing the emissions management dashboard interface 504 to generate and/or display a methane emissions intensity prediction, for example embodied in the methane emissions intensity predictions 360, specifically for a period of time corresponding to the selected prediction period. In the illustrated example, the time selector 506 is a drop box populated with a currently selected prediction period of “2023,” indicating that the information presented on the emissions management dashboard interface 504 in the illustrated example was generated for an upcoming (e.g., future) year 2023. In some embodiments, the time selector 506 may receive input indicative of a selected prediction period that corresponds to a remainder of a current year (e.g., calendar year), such as a time period beginning at a current instance of time at which the selection of the selected prediction period is received and ending at a subsequent, future instance of time marking an end to the current year. Accordingly, the methane emissions intensity predictions 360 may be generated and/or presented with respect to the remainder of the current year.

The prediction pane 508 may be a region or portion of the GUI 502 within which a methane emissions intensity prediction, for example embodied in the methane emissions intensity predictions 360, generated with respect to the selected prediction period may be displayed as textual information. Selection of a prediction period via the time selector 506 may cause the apparatus 200 to generate or retrieve a methane emissions intensity prediction, for example embodied in the methane emissions intensity predictions 360, associated with the selected prediction period and display the generated or retrieved prediction within the prediction pane 508. When a first methane emissions intensity prediction, for example embodied in the methane emissions intensity predictions 360, is already displayed in the prediction pane 508 for a first prediction period, selection of a second prediction period via the time selector 506 may cause the apparatus 200 to generate or retrieve a second methane emissions intensity prediction, for example embodied in the methane emissions intensity predictions 360, associated with the second prediction period and update the prediction pane 508 to display the second prediction in place of the first prediction.

The estimates pane 510 may be a region or portion of the GUI 502 within which various estimated quantities (e.g., production amount, methane emissions) associated with the selected prediction period may be displayed as textual information. These estimated quantities may correspond to features of the training data set and/or input data set (e.g., historical operational data 350, historical emissions data 352, simulated data 353), including intermediate values calculated from the historical and/or simulated data and used to calculate the predicted methane emissions intensity displayed in the prediction pane 508. As before, selection of a prediction period via the time selector 506 may cause the apparatus 200 to retrieve and/or calculate the estimated quantities specifically for the selected prediction period and display the calculated and/or retrieved quantities within the estimates pane 510. When first estimated quantities are already displayed in the estimates pane 510 for a first prediction period, selection of a second prediction period via the time selector 506 may cause the apparatus 200 to calculate or retrieve second estimated quantities associated with the second prediction period and update the estimates pane 510 to display the second estimated quantities in place of the first quantities.

The map pane 512 may be a region or portion of the GUI 502 within which a map image (e.g., a graphical depiction or map of one or more geographic regions, a captured overhead image or graphical depiction of a site, a graphical depiction of an operational system 102 or a portion thereof) is displayed. The map pane 512 may comprise location indicators 514, which may be graphical elements (e.g., icons) representing locations of different assets and/or components of operational systems, for example one or more of the operational system 102, different operational systems, for example one or more of the operational system 102, different sites containing one or more operational systems, for example one or more of the operational system 102, and/or different regions containing one or more sites. The location indicators 514 may be overlaid over the map image in different positions with respect to the map image, the different positions indicating locations of the objects represented by the location indicators 514. For example, a position at which a location indicator of the location indicators 514, 516 is overlaid on a map image in the map pane 512 may represent the location depicted within a portion of the map image that is at or in proximity to the position where the location indicator of the location indicators 514, 516 is overlaid. Accordingly, a location indicator of the location indicators 514, 516 overlaid on a map image at a particular position may indicate that an object represented by the location indicator of the location indicators 514, 516 has a location corresponding to the location depicted within a portion of the map image at the particular position. The locations indicated by the location indicators 514, 516 may represent geographic locations (e.g., coordinates, addresses, towns, cities, counties, states, countries, continents, or any regions thereof), physical locations within a site or operational system 102, and/or schematic locations within an operational system 102, to list a few examples.

The visual appearance (e.g., size, shape, hue, brightness) of the location indicators 514, 516 displayed as part of the map pane 512 may be determined and may vary (with respect to each other) based at least in part on one or more methane emissions intensity predictions 360, associated with the objects represented by the location indicators 514, 516. For example, the visual appearance of a particular location indicator of the location indicators 514, 516 may be determined based at least in part on the methane emissions intensity prediction, for example embodied in the methane emissions intensity predictions 360, generated for whatever asset, component, operational system 102, and/or group of operational systems, for example one or more of the operational system 102, (e.g., within particular sites or regions) is represented by the particular location indicator of the location indicators 514, 516. More particularly, the visual appearance of the location indicators 514, 516 may be determined based at least in part on a comparison of the relevant methane emissions intensity prediction, for example embodied in the methane emissions intensity predictions 360, with a targeted methane emissions intensity associated with that location. For example, the location indicators 514, 516 may include green location indicators 514 and red location indicators 516. The green location indicators 514 may be icons having a green hue that represent assets, components, systems, sites, and/or regions for which the corresponding methane emissions intensity prediction, for example embodied in the methane emissions intensity predictions 360, is determined to meet or satisfy, or be on track to meet or satisfy, a targeted methane emissions intensity associated with the represented assets, components, systems, sites, and/or regions represented by the green location indicators 514. Similarly, the red location indicators 516 may be icons having a red hue that represent assets, components, systems, sites, and/or regions for which the corresponding methane emissions intensity prediction, for example embodied in the methane emissions intensity predictions 360, is determined not to meet or satisfy, or be on track to fail to meet or satisfy, a targeted methane emissions intensity associated with the represented assets, components, systems, sites, and/or regions represented by the green location indicators 516. In the illustrated example, the map pane 512 comprises three green location indicators 514a, 514b, 514c and two red location indicators 516a, 516b.

The location indicators 514, 516 may also be interactable interface elements. More particularly, the location indicators 514, 516 may be selectable. In one example, selection of a location indicator of the location indicators 514, 516 may cause the apparatus 200 to update the emissions management dashboard interface 504 to display filtered information specific to the asset, component, system, site, and/or region represented by the selected location indicator of the location indicators 514, 516, including generating and/or retrieving a methane emissions intensity prediction, for example embodied in the methane emissions intensity predictions 360, specific to the asset, component, system, site, and/or region represented by the selected location indicator of the location indicators 514, 516 and updating the prediction pane 508 to display the generated and/or retrieved prediction.

Although example processing systems have been described in the figures herein, implementations of the subject matter and the functional operations described herein can be implemented in other types of digital electronic circuitry, or in computer software, firmware, or hardware, including the structures disclosed in this specification and their structural equivalents, or in combinations of one or more of them.

Embodiments of the subject matter and the operations described herein can be implemented in digital electronic circuitry, or in computer software, firmware, or hardware, including the structures disclosed in this specification and their structural equivalents, or in combinations of one or more of them. Embodiments of the subject matter described herein can be implemented as one or more computer programs, i.e., one or more modules of computer program instructions, encoded on computer storage medium for execution by, or to control the operation of, information/data processing apparatus. Alternatively, or in addition, the program instructions can be encoded on an artificially-generated propagated signal, e.g., a machine-generated electrical, optical, or electromagnetic signal, which is generated to encode information/data for transmission to suitable receiver apparatus for execution by an information/data processing apparatus. A computer storage medium can be, or be included in, a computer-readable storage device, a computer-readable storage substrate, a random or serial access memory array or device, or a combination of one or more of them. Moreover, while a computer storage medium is not a propagated signal, a computer storage medium can be a source or destination of computer program instructions encoded in an artificially-generated propagated signal. The computer storage medium can also be, or be included in, one or more separate physical components or media (e.g., multiple CDs, disks, or other storage devices).

The operations described herein can be implemented as operations performed by an information/data processing apparatus on information/data stored on one or more computer-readable storage devices or received from other sources.

The term “data processing apparatus” encompasses all kinds of apparatus, devices, and machines for processing data, including by way of example a programmable processor, a computer, a system on a chip, or multiple ones, or combinations, of the foregoing. The apparatus can include special purpose logic circuitry, e.g., an FPGA (field programmable gate array) or an ASIC (application-specific integrated circuit). The apparatus can also include, in addition to hardware, code that creates an execution environment for the computer program in question, e.g., code that constitutes processor firmware, a protocol stack, a repository management system, an operating system, a cross-platform runtime environment, a virtual machine, or a combination of one or more of them. The apparatus and execution environment can realize various different computing model infrastructures, such as web services, distributed computing and grid computing infrastructures.

A computer program (also known as a program, software, software application, script, or code) can be written in any form of programming language, including compiled or interpreted languages, declarative or procedural languages, and it can be deployed in any form, including as a stand-alone program or as a module, component, subroutine, object, or other unit suitable for use in a computing environment. A computer program may, but need not, correspond to a file in a file system. A program can be stored in a portion of a file that holds other programs or information/data (e.g., one or more scripts stored in a markup language document), in a single file dedicated to the program in question, or in multiple coordinated files (e.g., files that store one or more modules, sub-programs, or portions of code). A computer program can be deployed to be executed on one computer or on multiple computers that are located at one site or distributed across multiple sites and interconnected by a communications network.

The processes and logic flows described herein can be performed by one or more programmable processors executing one or more computer programs to perform actions by operating on input information/data and generating output. Processors suitable for the execution of a computer program include, by way of example, both general and special purpose microprocessors, and any one or more processors of any kind of digital computer. Generally, a processor will receive instructions and information/data from a read-only memory or a random access memory or both. The essential elements of a computer are a processor for performing actions in accordance with instructions and one or more memory devices for storing instructions and data. Generally, a computer will also include, or be operatively coupled to receive information/data from or transfer information/data to, or both, one or more mass storage devices for storing data, e.g., magnetic, magneto-optical disks, or optical disks. However, a computer need not have such devices. Devices suitable for storing computer program instructions and information/data include all forms of non-volatile memory, media and memory devices, including by way of example semiconductor memory devices, e.g., EPROM, EEPROM, and flash memory devices; magnetic disks, e.g., internal hard disks or removable disks; magneto-optical disks; and CD-ROM and DVD-ROM disks. The processor and the memory can be supplemented by, or incorporated in, special purpose logic circuitry.

To provide for interaction with a user, embodiments of the subject matter described herein can be implemented on a computer having a display device, e.g., a CRT (cathode ray tube) or LCD (liquid crystal display) monitor, for displaying information/data to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's client device in response to requests received from the web browser.

Embodiments of the subject matter described herein can be implemented in a computing system that includes a back-end component, e.g., as an information/data server, or that includes a middleware component, e.g., an application server, or that includes a front-end component, e.g., a client computer having a graphical user interface or a web browser through which a user can interact with an implementation of the subject matter described herein, or any combination of one or more such back-end, middleware, or front-end components. The components of the system can be interconnected by any form or medium of digital information/data communication, e.g., a communications network. Examples of communications networks include a local area network (“LAN”) and a wide area network (“WAN”), an inter-network (e.g., the Internet), and peer-to-peer networks (e.g., ad hoc peer-to-peer networks).

The computing system can include clients and servers. A client and server are generally remote from each other and typically interact through a communications network. The relationship of client and server arises by virtue of computer programs running on the respective computers and having a client-server relationship to each other. In some embodiments, a server transmits information/data (e.g., an HTML page) to a client device (e.g., for purposes of displaying information/data to and receiving user input from a user interacting with the client device). Information/data generated at the client device (e.g., a result of the user interaction) can be received from the client device at the server.

While this specification contains many specific implementation details, these should not be construed as limitations on the scope of any disclosures or of what may be claimed, but rather as descriptions of features specific to particular embodiments of particular disclosures. Certain features that are described herein in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described. Other embodiments are within the scope of the following claims. In some cases, the actions recited in the claims can be performed in a different order and still achieve desirable results. In addition, the processes depicted in the accompanying figures do not necessarily require the particular order shown, or sequential order, to achieve desirable results. In certain implementations, multitasking and parallel processing may be advantageous.

It is to be understood that the disclosure is not to be limited to the specific embodiments disclosed, and that modifications and other embodiments are intended to be included within the scope of the appended claims. Although specific terms are employed herein, they are used in a generic and descriptive sense only and not for purposes of limitation, unless described otherwise.

What is claimed is:

1. An apparatus comprising at least one processor and at least one non-transitory memory comprising program code stored thereon, wherein the at least one non-transitory memory and the program code are configured to, with the at least one processor, cause the apparatus to at least:
receive one or more projected production parameters and emissions reduction strategy information associated with one or more operational systems and corresponding to a period of time, wherein the one or more projected production parameters correspond to planned operation of the one or more operational systems in the period of time, and wherein the emissions reduction strategy information indicates one or more planned methane emissions reduction strategies to be implemented with respect to the one or more operational systems in the period of time; and
generate, using a methane emissions intensity prediction model, a methane emissions intensity prediction corresponding to the one or more operational systems and the period of time based at least in part on the one or more projected production parameters, the emissions reduction strategy information, historical operational data associated with the one or more operational systems, and historical emissions data associated with the one or more operational systems.

2. The apparatus of claim 1, wherein the methane emissions intensity prediction model comprises a machine learning model trained based at least in part on the historical operational data and the historical emissions data.

3. The apparatus of claim 1, wherein the one or more projected production parameters include planned operating conditions, planned operating capacity, and/or planned operating modes of the one or more operational systems during the period of time.

4. The apparatus of claim 1, wherein the historical operational data indicates historical production parameters corresponding to past operation of the one or more operational systems.

5. The apparatus of claim 4, wherein the historical production parameters include past operating conditions, past operating capacity, and/or past operating modes of the one or more operational systems during the past operation of the one or more operational systems.

6. The apparatus of claim 4, wherein the historical emissions data indicates methane emissions produced by the one or more operational systems and measured by emissions sensors during the past operation of the one or more operational systems.

7. The apparatus of claim 6, wherein the methane emissions intensity prediction is generated based at least in part on correlations between the methane emissions of the historical emissions data and the historical production parameters of the historical operational data.

8. The apparatus of claim 1, wherein the methane emissions intensity prediction is generated based at least in part on simulated emissions data associated with the one or more operational systems, the simulated emissions data indicating estimated methane emissions corresponding to simulated production parameters associated with the one or more operational systems.

9. The apparatus of claim 8, wherein the methane emissions intensity prediction is generated based at least in part on correlations between the estimated methane emissions and the simulated production parameters.

10. The apparatus of claim 8, wherein the methane emissions intensity prediction model comprises a machine learning model trained based at least in part on the simulated emissions data.

11. A computer-implemented method comprising:
receiving one or more projected production parameters and emissions reduction strategy information associated with one or more operational systems and corresponding to a period of time, wherein the one or more projected production parameters correspond to planned operation of the one or more operational systems in the period of time, and wherein the emissions reduction strategy information indicates one or more planned methane emissions reduction strategies to be implemented with respect to the one or more operational systems in the period of time; and
generating, using a methane emissions intensity prediction model, a methane emissions intensity prediction corresponding to the one or more operational systems and the period of time based at least in part on the one or more projected production parameters, the emissions reduction strategy information, historical operational data associated with the one or more operational systems, and historical emissions data associated with the one or more operational systems.

12. The method of claim 11, wherein the methane emissions intensity prediction model comprises a machine learning model trained based at least in part on the historical operational data and the historical emissions data.

13. The method of claim 11, wherein the one or more projected production parameters include planned operating conditions, planned operating capacity, and/or planned operating modes of the one or more operational systems during the period of time.

14. The method of claim 11, wherein the historical operational data indicates historical production parameters corresponding to past operation of the one or more operational systems.

15. The method of claim 14, wherein the historical production parameters include past operating conditions, past operating capacity, and/or past operating modes of the one or more operational systems during the past operation of the one or more operational systems.

16. The method of claim 14, wherein the historical emissions data indicates methane emissions produced by the one or more operational systems and measured by emissions sensors during the past operation of the one or more operational systems.

17. The method of claim 16, wherein the generating of the methane emissions intensity prediction comprises generating the methane emissions intensity prediction based at least in part on correlations between the methane emissions of the historical emissions data and the historical production parameters of the historical operational data.

18. The method of claim 11, wherein the generating of the methane emissions intensity prediction comprises generating the methane emissions intensity prediction based at least in part on simulated emissions data associated with the one or more operational systems, the simulated emissions data indicating estimated methane emissions corresponding to simulated production parameters associated with the one or more operational systems.

19. The apparatus of claim 18, wherein the generating of the methane emissions intensity prediction comprises generating the methane emissions intensity prediction based at least in part on correlations between the estimated methane emissions and the simulated production parameters.

20. A computer program product comprising at least one non-transitory computer-readable storage medium having computer-readable program code portions stored therein, the computer-readable program code portions comprising an executable portion configured to:
receive one or more projected production parameters and emissions reduction strategy information associated with one or more operational systems and corresponding to a period of time, wherein the one or more projected production parameters correspond to planned operation of the one or more operational systems in the period of time, and wherein the emissions reduction strategy information indicates one or more planned methane emissions reduction strategies to be implemented with respect to the one or more operational systems in the period of time; and
generate, using a methane emissions intensity prediction model, a methane emissions intensity prediction corresponding to the one or more operational systems and the period of time based at least in part on the one or more projected production parameters, the emissions reduction strategy information, historical operational data associated with the one or more operational systems, and historical emissions data associated with the one or more operational systems.
